(19) United States
(12) Patent Application Publication
(10) Pub. No.: US 2016/0300592 A1
(43) Pub. Date: Oct. 13, 2016

(54) HEAT-ASSISTED-MAGNETIC-RECORDING HEAD, SEMICONDUCTOR LASER ELEMENT, AND METHOD FOR MANUFACTURING SEMICONDUCTOR LASER ELEMENT

(71) Applicant: SHARP KABUSHIKI KAISHA, Osaka-Shi (JP)

(72) Inventors: Toshiyuki KAWAKAMI, Osaka-shi (JP); Akira ARIYOSHI, Osaka-shi (JP)

(73) Assignee: SHARP KABUSHIKI KAISHA, Osaka-shi (JP)

(21) Appl. No.: 14/778,538

(22) PCT Filed: Sep. 2, 2014
(86) PCT No.: PCT/JP2014/073048

§ 371 Date: Sep. 18, 2015

(30) Foreign Application Priority Data
Oct. 17, 2013 (JP) 2013-216593

(51) Int. Cl. G11B 7/125; H01S 5/32; H01S 5/22; H01S 5/343; G11B 7/22; H01S 5/223

(52) U.S. Cl. CPC G11B 7/125; G11B 7/22; H01S 5/223; H01S 5/2202; H01S 5/34313; H01S 5/3211; G11B 2005/0021

(57) ABSTRACT

In a semiconductor laser device including a semiconductor laser element that emits laser light from an emission region thereof, a cap having a peripheral wall and a ceiling wall that cover the semiconductor laser element and having a window portion formed in the ceiling wall to face the emission region, and a transparent optical member that fills the window portion, the optical member is formed by curing a liquid resin and holds the ceiling wall, and a light incidence surface of the optical member faces the emission region and is formed by natural flow of the liquid resin.

### CROSS REFERENCE TO RELATED APPLICATIONS

This application is a U.S. National Phase patent application of PCT/JP2014/073048, filed on Sep. 2, 2014, which claims priority to Japanese Application No. 2013-216593, filed on Oct. 17, 2013, each of which is hereby incorporated by reference in the present disclosure in its entirety.

### FIELD OF THE INVENTION

The present invention relates to a semiconductor laser element of one-surface-two-contact type and a heat-assisted magnetic recording head using the same. Besides, the present invention relates to a method for manufacturing the semiconductor laser element of one-surface-two-contact type.

### BACKGROUND OF THE INVENTION

Following development of information societies in recent years, high-definition of a sound and image is progressing and data communication amount on the internet is increasing remarkably. Besides, because of development of so-called cloud computing, data amount stored on the internet is increasing extraordinarily dramatically, and it is forecast that this tendency continues to rise in the future. Under these circumstances, expectations are increasing for large-capacity information recording systems that store electronic data.

As large-capacity information recording apparatuses, magnetic recording apparatuses such as a hard disc drive and the like are playing a major role. To increase recoding density of the magnetic recording apparatuses, vertical magnetic recording capable of achieving minuscule recording bits are realized, further, development of a heat-assisted magnetic recording technology is underway.

As to heat-assisted magnetic recording, a magnetic recording medium, which is formed of a magnetic material having large magnetic anisotropic energy, is used in such a manner that magnetization stabilizes. And, an anisotropic magnetic field at a data writing portion of the magnetic recording medium is lowered by heating, and immediately thereafter, a writing magnetic field is added to perform minuscule-size writing. As a method for heating the magnetic recording medium, it is general to use light such as near-field light and the like, and as a light source for the purpose, a semiconductor laser element is generally used.

A patent literature 1 discloses a conventional heat-assisted magnetic recording head that includes a semiconductor laser element. FIG. 12 shows a schematic front view of the heat-assisted magnetic recording head. The heat-assisted magnetic recording head 1 includes a slider 10 and a semiconductor laser element 30, and is disposed over a magnetic disc (not shown).

The slider 10 floats over the rotating magnetic disc, and one end portion opposing the magnetic disc is provided with a magnetic recording portion 13 and a magnetic reproducing portion 14. An optical waveguide 15 is disposed near the magnetic recording portion 13, and an element (not shown) for generating near-field light is disposed in the optical waveguide 15.

As to the semiconductor laser element 30, a semiconductor multilayer 32 is formed on a substrate 31, and a stripe-shaped optical waveguide 36 is formed by means of a ridge structure of the semiconductor multilayer 32. A first contact (not shown) is formed on a bottom surface of the substrate 31, and a second contact (not shown) is formed on an upper surface of the semiconductor multilayer 32.

A front surface 21a of a sub-mount 21 is bonded to a disposition surface 10a of a rear side (side opposite to the magnetic disc) of the slider 10 via an adhesive 19. The semiconductor laser element 30 is bonded to a vertical surface 21b perpendicular to the front surface 21a of the sub-mount 21 via a solder material 29 disposed on the second contact. At this time, an emitting portion 36a of one facet of the optical waveguide 36 is disposed to oppose the optical waveguide 15 of the slider 10.

Besides, the vertical surface 21b of the sub-mount 21 is provided with a terminal portion (not shown) that electrically communicates with the second contact via the solder material 29. In this way, the first contact and the terminal portion are disposed to face the same direction (left direction in the figure), and it is possible to easily connect a lead wire to each of the first contact and the terminal portion.

When a voltage is applied between the first contact and the terminal portion, laser light is emitted from the emitting portion 36a. The emitted laser light from the emitting portion 36a propagates in the optical waveguide 15 of the slider 10 to generate near-field light. As to the magnetic disc, an anisotropic magnetic field weakens locally because of heat of the near-field light, and magnetic recording is performed by the magnetic recording portion 13. Data recorded on the magnetic disc are read by the magnetic reproducing portion 14.

Besides, heat generated from the semiconductor laser element 30 is conducted to the sub-mount 21 via the solder material 29 and conducted to the slider 10 via the adhesive 19. In this way, the heat generated from the semiconductor laser element 30 is radiated from the sub-mount 21 and the slider 10.

As to the semiconductor laser element 30, the first contact and the second contact are respectively disposed on the bottom surface of the substrate 31, and the upper surface of the semiconductor multilayer 32 in such a manner that either of the first contact and the second contact is disposed on either of both surfaces of the substrate 31 to oppose each other. In contrast to this, a non-patent literature 1 discloses a semiconductor laser element of one-surface-two-contact type in which the first contact and the second contact are disposed on one surface of a substrate.

FIG. 13 shows a front view of a semiconductor laser element 40 of the one-surface-two-contact type. In the semiconductor laser element 40, a semiconductor multilayer 42 is laminated on a substrate 41 such as sapphire or the like. The semiconductor multilayer 42 is formed by means of epitaxial growth by using a ground layer (not shown) disposed on the substrate 41 as a ground, and has an n-type semiconductor layer 43, an active layer 44, and a p-type semiconductor layer 45 in this order from the substrate 41.

Besides, a concave portion 51 and a light emitting portion 52 are formed adjacently to each other on the substrate 41 by means of the semiconductor multilayer 42. The concave portion 51 is formed by carving the semiconductor multilayer 42 to a middle portion of the n-type semiconductor layer 43 by means of etching. A first contact 47 is disposed on a bottom surface of the concave portion 51.

As to the light emitting portion 52, a stripe-shaped narrow-width ridge portion 49 is disposed to protrude on an upper portion of the semiconductor multilayer 42. The ridge portion 49 is formed by carving both sides of the ridge portion 49 to a middle portion of the p-type semiconductor layer 45 by means of etching. An upper surface of the ridge portion 49 is provided with a second contact 48. Active layer 44 is injected an electric current via the ridge portion 49, and forms a stripe-shaped optical waveguide 46, so that laser light is emitted from an emitting portion 46a of a facet of optical waveguide 46.

In the meantime, the first, second contacts 47, 48 are disposed on the one surface of the substrate 41; accordingly, it is possible to easily connect a lead wire to each of the first, second contacts 47, 48.

### Patent Literature

PLT1: JP No. 4635607 (page 7-page 12, FIG. 1)

PLT2: JP-A-2012-18747 (page 7-page 22, FIG. 2)

PLT3: JP-A-2003-45004 (page 5-page 11, FIG. 1)

### Non-Patent Literature

Non-patent document 1: Bernard Gil, “Group III-Nitride Semiconductor Compounds”, (Great Britain), Clarendon Press, Apr. 23, 1998, p. 405

### SUMMARY OF THE INVENTION

According to the heat-assisted magnetic recording head 1 disclosed in the patent literature 1, the semiconductor laser element 30 is mounted on the vertical surface 21b of the sub-mount 21 bonded to the slider 10. Because of this, if the semiconductor laser element 30 inclines in a surface parallel to the vertical surface 21b or in a surface perpendicular to the front surface 21a and vertical surface 21b, it becomes hard to perform the positioning between the emitting portion 36a and the optical waveguide 15. Accordingly, it is necessary to position the semiconductor laser element 30 at high accuracy with respect to the sub-mount 21, so that there is a problem that the man-hours of the heat-assisted magnetic recording head 1 becomes large and the yield declines.

Besides, the heat generated from the semiconductor laser element 30 is conducted to the sub-mount 21 via the solder material 29, thereafter, conducted to the slider 10 via the adhesive 19. Because of this, two interfaces exist on the heat radiation route of the heat-assisted magnetic recording head 1; accordingly, the heat radiation of the heat-assisted magnetic recording head 1 declines. Because a failure rate of the semiconductor laser element 30 increases exponentially for temperature rising, there also is a problem that reliability of the heat-assisted magnetic recording head 1 deteriorates because of the decline in the heat radiation.

On the other hand, if a volume of the sub-mount 21 is made large to improve the heat radiation of the heat-assisted magnetic recording head 1, a weight of the heat-assisted magnetic recording head 1 becomes heavy. In this way, there is a problem that attitude control of the heat-assisted magnetic recording head 1 floating over the magnetic disc becomes hard.

To solve these problems, it is conceivable that the sub-mount 21 is removed and an emitting facet 40a of a front surface of the semiconductor laser element 40 of one-surface-two-contact type is boned to the disposition surface 10a of the slider 10. According to this structure, the positioning of the semiconductor laser element 40 with respect to the sub-mount 21 becomes unnecessary; accordingly, it is possible to achieve reduction in the man-hours of the heat-assisted magnetic recording head 1 and improvement in the yield. Besides, there is only one interface on the heat radiation route of the heat-assisted magnetic recording head 1; accordingly, the heat radiation is improved.

However, in the semiconductor laser element 40, the first contact 47 is disposed near the substrate 41 (e.g., several micrometers). Because of this, to improve the heat radiation, if the adhesive 19 is applied to a wide area of the emitting facet 40a of the semiconductor laser element 40, there is a case where the adhesive 19 adheres to the first contact 47. In this way, a problem occurs in which the connection of a lead to the first contact 47 becomes hard and the reduction in the man-hours of the heat-assisted magnetic recording head 1 cannot be achieved sufficiently.

Besides, the substrate 41 is formed of a material such as sapphire or the like different from the semiconductor multilayer 42, and the heat conduction at the interface between the substrate 41 and the semiconductor multilayer 42 is low. Because of this, a problem also occurs in which the heat radiation of the heat-assisted magnetic recording head 1 cannot be improved sufficiently.

Further, during a production time of the semiconductor laser element 40, first, the semiconductor multilayer 42 is formed on the wafer-shaped substrate 41. Thereafter, a scribe groove is formed in a direction perpendicular to the ridge portion 49 and in a direction parallel to the ridge portion 49, and stress is exerted onto the scribe groove to cleave the substrate 41 to obtain the discrete semiconductor laser element 40. Here, the light emitting portion 52 and the concave portion 51 are repeated alternately; accordingly, there is a case where the cleavage direction deviates and flatness of the emitting facet 40a deteriorates. In this way, a problem also occurs in which tight contact between the semiconductor laser element 40 and the slider 10 declines and the heat radiation of the heat-assisted magnetic recording head 1 cannot be improved sufficiently.

In addition, a volume difference between the light emitting portion 52 and the concave portion 51 is large; accordingly, internal strain is formed unevenly. In this way, there is also a problem in which the tight contact between the semiconductor laser element 40 and the slider 10 further deteriorates and stability of the laser light emission by the semiconductor laser element 40 deteriorates.

It is an object of the present invention to provide: a heat-assisted magnetic recording head that is capable of achieving the man-hours reduction and yield improvement and improving the heat radiation and the stability of laser light emission; a semiconductor laser element used for the heat-assisted magnetic recording head; and a method for manufacturing the semiconductor laser element.

To achieve the object, a semiconductor laser element according to the present invention includes: a substrate formed of a semiconductor; a light emitting portion that includes a semiconductor multilayer in which the substrate is used as a ground to laminate successively a first electro-conductive-type semiconductor layer, an active layer, and a second electro-conductive-type semiconductor layer by means of epitaxial growth; and a stripe-shaped optical waveguide is formed of the active layer; an annular protective wall that is formed of the semiconductor multilayer adjacently to the light emitting portion and encloses a concave portion which uses the substrate or the first electro-conductive-type semiconductor layer as a bottom surface; a first contact disposed on the bottom surface of the concave portion; and a second contact disposed on an upper surface of the light emitting portion.

Besides, the present invention has a feature that in the semiconductor laser element having the above structure, the light emitting portion and the protective wall are separated by a separation groove that uses the substrate or the first electro-conductive-type semiconductor layer as a bottom surface.

Besides, the present invention has a feature that in the semiconductor laser element having the above structure, the protective wall is opened through a surface that opposes the light emitting portion.

Besides, the present invention has a feature that in the semiconductor laser element having the above structure, the substrate and the active layer are formed of a GaAs-based semiconductor.

Besides, a heat-assisted magnetic recording head according to the present invention has a feature to include: the semiconductor laser element and a slider that performs magnetic recording; wherein an end surface of the substrate perpendicular to the optical waveguide is bonded to the slider.

Besides, a method for manufacturing the semiconductor laser element according to the present invention has a feature to include: a semiconductor multilayer forming step for forming a semiconductor multilayer in which a first electro-conductive-type semiconductor layer, an active layer, and a second electro-conductive-type semiconductor layer are successively laminated on a substrate formed of a semiconductor; a ridge forming step for forming a stripe-shaped ridge by etching the second electro-conductive-type semiconductor layer; a concave portion forming step for forming a concave portion enclosed by a protective wall by etching a region adjacent to the ridge to a layer lower than the active layer; a first metal film laminating step for forming a first metal film on a bottom surface of the concave portion; and a second metal film forming step for laminating a second metal film on the first metal film and the ridge portion; wherein a first contact is formed on the bottom surface of the concave portion by means of the first metal film and the second metal film; and a second contact is formed on the ridge portion by means of the second metal film.

According to the present invention, in the semiconductor laser element, the substrate is used as a ground to form the semiconductor multilayer by means of epitaxial growth, and the protective wall enclosing the concave portion, in which the first contact is disposed, and the light emitting portion, which has the optical guide and in which the second contact is disposed, are formed by means of the semiconductor multilayer adjacently to each other.

In this way, it is possible to form the heat-assisted magnetic recording head by boding a bond surface perpendicular to the optical waveguide of the semiconductor laser element to the slider. Because of this, it is possible to easily perform the positioning between the semiconductor laser element and the slider. Besides, when bonding the semiconductor laser element, it is possible to prevent an adhesive from adhering to the first contact by means of the protective wall and to easily connect a lead wire to the first contact. Accordingly, it is possible to achieve the man-hours reduction of the heat-assisted magnetic recording head and the yield improvement.

Further, the substrate and the semiconductor multilayer are joined to each other by a continuous crystal lattice, and heat conduction between both improves. Besides, when forming the semiconductor multilayer on the wafer-shaped substrate and separating it into pieces, a scribe groove is formed on the light emitting portion and the protective wall; accordingly, flatness of the bond surface formed of a cleavage surface improves. Accordingly, it is possible to improve heat radiation of the heat-assisted magnetic recording heat that uses the semiconductor laser element. In addition, a volume difference between the light emitting portion and the protective wall is small; accordingly, it is possible to even an internal strain of the semiconductor laser element and thereby to improve the stability of the laser light emission.

Besides, according to the present invention, the method for manufacturing the semiconductor laser element includes: the first metal film forming step for laminating the first metal film on the bottom surface of the concave portion enclosed by the protective wall, and the second metal film forming step for laminating the second metal film on the first metal film and the ridge portion; wherein the first contact is formed by means of the first metal film and the second metal film; and the second contact is formed by means of the second metal film. In this way, during the time of forming the second metal film, it is possible to prevent the first metal film from being etched and thereby to maintain a desired shape of the first contact.

### BRIEF DESCRIPTION OF THE DRAWINGS

FIG. 1 is a front view showing a heat-assisted magnetic recording head according to a first embodiment of the present invention.

FIG. 2 is a perspective view showing a semiconductor laser element of the heat-assisted magnetic recording head according to the first embodiment of the present invention.

FIG. 3 is a step flow chart of the semiconductor laser element of the heat-assisted magnetic recording head according to the first embodiment of the present invention.

FIG. 4 is a front view showing a semiconductor multilayer forming step of the semiconductor laser element of the heat-assisted magnetic recording head according to the first embodiment of the present invention.

FIG. 5 is a front view showing a ridge portion forming step of the semiconductor laser element of the heat-assisted magnetic recording head according to the first embodiment of the present invention.

FIG. 6 is a front cross-sectional view showing a concave portion forming step of the semiconductor laser element of the heat-assisted magnetic recording head according to the first embodiment of the present invention.

FIG. 7 is a front cross-sectional view showing a first metal film forming step of the semiconductor laser element of the heat-assisted magnetic recording head according to the first embodiment of the present invention.

FIG. 8 is a front cross-sectional view showing a buried layer forming step of the semiconductor laser element of the heat-assisted magnetic recording head according to the first embodiment of the present invention.

FIG. 9 is a front cross-sectional view showing a second metal film forming step of the semiconductor laser element of the heat-assisted magnetic recording head according to the first embodiment of the present invention.

FIG. 10 is a perspective view showing a semiconductor laser element of a heat-assisted magnetic recording head according to a second embodiment of the present invention.

FIG. 11 is a perspective view showing a semiconductor laser element of a heat-assisted magnetic recording head according to a third embodiment of the present invention.

FIG. 12 is a front view showing a conventional heat-assisted magnetic recording head.

FIG. 13 is a front view showing a conventional semiconductor laser element of one-surface-two-contact type

### DETAILED DESCRIPTION OF THE INVENTION

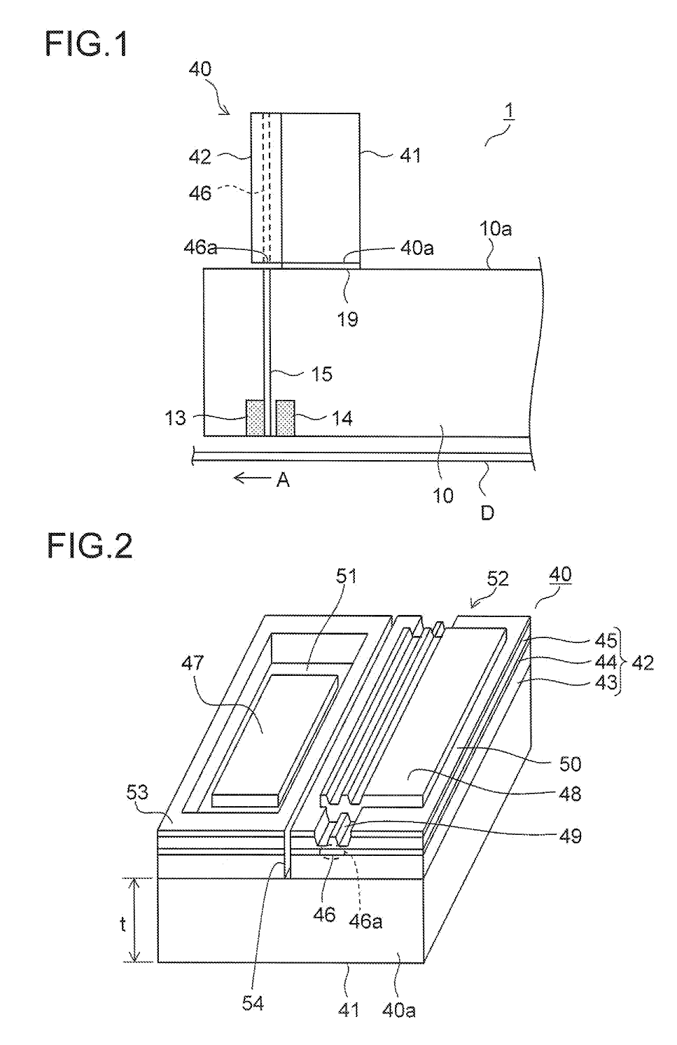

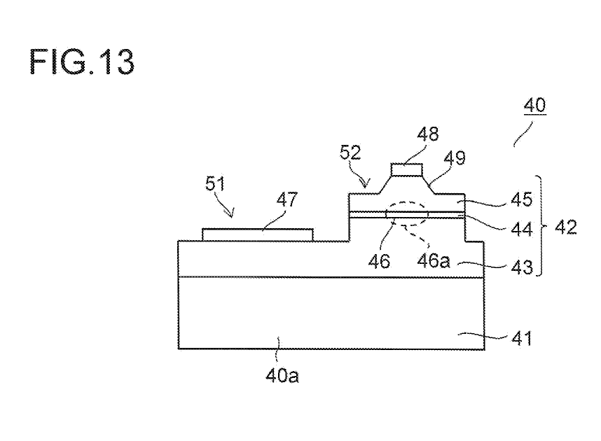

Hereinafter, embodiments of the present invention are described with reference to the drawings. For the sake of description, the same portions as the conventional examples shown in FIG. 12 and FIG. 13 are indicated by the same reference numbers. FIG. 1 shows a front view of a heat-assisted magnetic recording head according to a first embodiment. A heat-assisted magnetic recording head 1 is incorporated in a HDD device and the like and supported by a suspension (not shown) to be disposed over a magnetic disc movably in a shaft direction.

The heat-assisted magnetic recording head 1 includes a slider 10 that opposes the magnetic disc D and a semiconductor laser element 40 bonded to the slider 10 by means of a heat-conductive adhesive 19. The slider 10 floats over the magnetic disc D that rotates in an arrow A direction, and has a magnetic recording portion 13 and a magnetic reproducing portion 14 at an end portion on a medium exit side. The magnetic recording portion 13 performs magnetic recording and the magnetic reproducing portion 14 detects magnetization of the magnetic disc D and outputs it.

An optical waveguide 15, which conducts the laser light emitted from the semiconductor laser element 40, is disposed near the magnetic recording portion 13. The optical waveguide 15 is provided therein with an element (not shown) that generates near-field light.

As detailed later, in the semiconductor laser element 40, a semiconductor multilayer 42 is formed on a substrate 41, and a stripe-shaped optical waveguide 46 is formed by means of a ridge structure of the semiconductor multilayer 42. An emitting facet 40a perpendicular to the optical waveguide 46 of the semiconductor laser element 40 is bonded to a disposition surface 10a of a rear side (opposite to the magnetic disc) of the slider 10 via the adhesive 19. At this time, an emitting portion 46a of one facet of the optical waveguide 46 is disposed to oppose the optical waveguide 15. The sub-mount 21 (see FIG. 12) shown in the conventional example is removed; accordingly, it is possible to achieve a light weight of the heat-assisted magnetic recording head 1.

FIG. 2 shows a perspective view of the semiconductor laser element 40. In the semiconductor laser element 40, the semiconductor multilayer 42 is laminated on the substrate 41. The semiconductor multilayer 42 has an n-type semiconductor layer 43, an active layer 44, and a p-type semiconductor layer 45 in this order from the substrate 41.

Besides, a light emitting portion 52 and an annular protective wall 53 formed by means of the semiconductor multilayer 42 are formed on the substrate 41 adjacently to each other via a separation groove 54. The concave portion 51 enclosed by the annular protective wall 53 is formed by carving the semiconductor multilayer 42 to the substrate 41 or a middle portion of n-type semiconductor layer 43 by means of etching. The first contact 47 is disposed on the bottom surface of the concave portion 51.

As to the light emitting portion 52, a stripe-shaped narrow-width ridge portion 49 is disposed to protrude on an upper portion of the semiconductor multilayer 42. The ridge portion 49 is formed by carving both sides to a middle portion of the p-type semiconductor layer 45 by means of etching. An upper surface of the light emitting portion 52 is provided with a buried layer 50 formed of an insulating film except for an upper surface of the ridge portion 49, and the second contact 48 is formed on upper surfaces of the ridge portion 49 and buried layer 50. Active layer 44 is injected an electric current injected via the ridge portion 49, and forms the stripe-shaped optical waveguide 46, so that the laser light is emitted from the emitting portion 46a of the facet of optical waveguide 46.

In the meantime, the first, second contacts 47, 48 are disposed on the one surface of the substrate 41; accordingly, it is possible to easily connect a lead wire to each of the first, second contacts 47, 48.

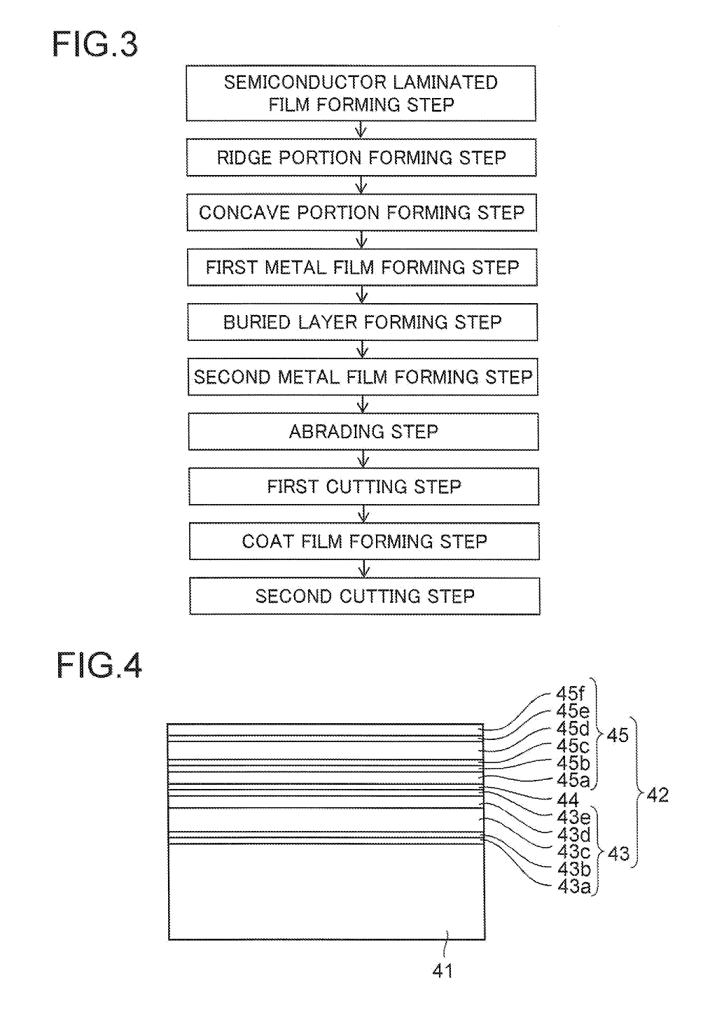

FIG. 3 shows a step flow chart of the semiconductor laser element 40. As to the semiconductor laser element 40, a semiconductor multilayer forming step, a ridge portion forming step, a concave portion forming step, a first metal film forming step, a buried layer forming step, a second metal film forming step, and a lapping step are performed successively on the wafer-shaped substrate 41 (see FIG. 2). Thereafter, a first cutting step, a coat film forming step, and a second cutting step are performed successively, so that the wafer is divided into pieces to obtain the discrete semiconductor laser element 40.

FIG. 4 shows a front view of the semiconductor multilayer forming step. In the semiconductor multilayer forming step, the substrate 41 formed of GaAs is used as a ground to form the semiconductor multilayer 42 by means of epitaxial growth of a GaAs-based semiconductor by using metal organic chemical vapor deposition (MOCVD), molecular beam epitaxy (MBE) and the like.

In other words, the substrate 41 is provided thereon with: a first buffer layer 43a, a second buffer layer 43b, an n-type clad layer 43c, an n-side light guide layer 43d, a hole barrier layer 43e, the active layer 44, a p-side light guide layer 45a, a first p-type clad layer 45b, an etch stop layer 45c, a second p-type clad layer 45d, an intermediate layer 45e, and a cap layer 45f in this order produced by means of epitaxial growth.

A multilayer n-type semiconductor layer 43 is composed of the first buffer layer 43a, the second buffer layer 43b, the n-type clad layer 43c, the n-side light guide layer 43d, and the hole barrier layer 43e. A multilayer p-type semiconductor layer 45 is composed of the p-side light guide layer 45a, the first p-type clad layer 45b, the etch stop layer 45c, the second p-type clad layer 45d, the intermediate layer 45e, and the cap layer 45f.

The first buffer layer 43a is formed of n-type GaAs. The second buffer layer 43b is formed of n-type GaInP. The n-type clad layer 43c is formed of n-type AlGaInP. The n-side light guide layer 43d is formed of n-type AlGaAs. The hole barrier layer 43e is formed of AlGaAs. The active layer 44 is formed into a multiple quantum well structure by means of InGaAs and AlGaAs.

The p-side light guide layer 45a is formed of p-type AlGaAs. The first p-type clad layer 45b is formed of p-type AlGaInP. The etch stop layer 45c is formed of p-type GaInP. The second p-type clad layer 45d is formed of p-type AlGaInP. The intermediate layer 45e is formed of p-type GaInP. The cap layer 45f is formed of p-type GaAs. In the meantime, it is possible to suitably change the order and composition of each layer to be optimum for the designing of the semiconductor laser element 40.

The substrate 41 and the semiconductor multilayer 42 including the active layer 44 are formed of semiconductors joined to each other by lattice combination; accordingly, the semiconductor multilayer 42 is formed by means of epitaxial growth by using the substrate 41 as a ground. Because of this, the substrate 41 and the semiconductor multilayer 42 are joined to each other by means of continuous crystal lattice, and it is possible to improve heat conduction between both.

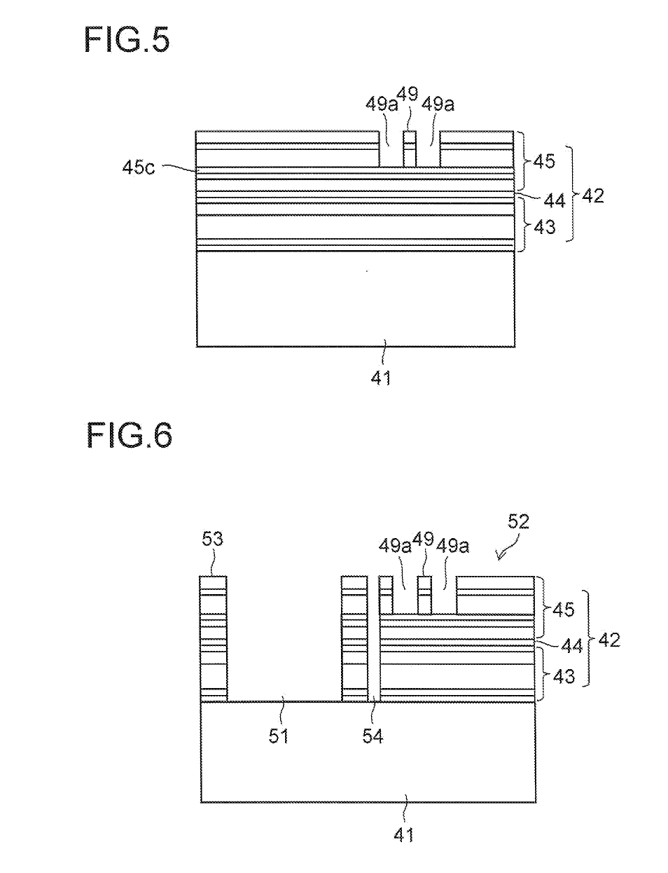

FIG. 5 shows a front view of the ridge portion forming step. In the ridge portion forming step, a predetermined region of the semiconductor multilayer 42 is provided with a mask (not shown) by means of a photolithography technique. Next, the n-type semiconductor layer 45, that is, a layer higher than the etch stop layer 45c, is removed by dry etching and wet etching to form a pair of groove portions 49a, thereafter, the mask is removed. In this way, the narrow-width (e.g., 2 μm) mesa-shaped ridge portion 49 is formed between the pair of groove portions 49a to have a stripe shape that extends in a direction perpendicular to the emitting facet 40a (see FIG. 2). It is possible to protect the ridge portion 49 by leaving terraces equal to each other in height on both sides of the ridge portion 49.

FIG. 6 shows a front cross-sectional view of the concave portion forming step. In the concave portion forming step, a predetermined region of the semiconductor multilayer 42 is provided with a mask (not shown) formed of SiO₂ by means of the photolithography technique and etching. Next, the trench-shaped concave portion 51 and the separation groove 54, which use the substrate 41 as the bottom surface, are formed by means of dry etching and wet etching, and the mask is removed. In this way, the annular protective wall 53 is formed around the concave portion 51.

Besides, the protective wall 53 is separated from the light emitting portion 52 having the ridge portion 49 by means of the separation groove 54. The separation groove 54 may be formed in a step different form the concave portion 51. However, by forming them at the same time, it is possible to reduce the man-hours.

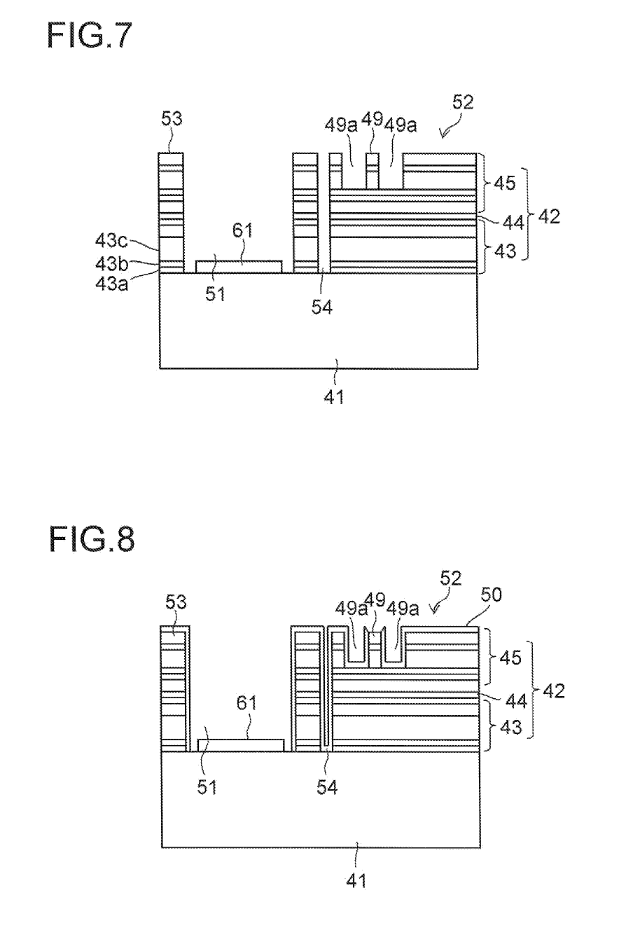

FIG. 7 shows a front cross-sectional view of the first metal film forming step. In the first metal film forming step, a first metal film 61, which is a layer under the first contact 47 (see FIG. 2), is formed on the bottom surface of the concave portion 51. As to the first metal film 61, a film is formed on a whole wafer surface by using AuGe/Ni, NiGe (In) or the like having a general ohmic structure, and a pattern is formed by using photolithography and etching. Thereafter, annealing is performed at about 200 to 450° C.

In the meantime, to form an N-type ohmic contact on the bottom surface of the concave portion 51 by means of the first metal film 61, the concave portion 51 using the substrate 41 formed of GaAs as the bottom surface is formed in the concave portion forming step. At this time, in a case where it is possible to form the ohmic contact by raising the doping concentration of the first buffer layer 43a, second buffer layer 43b or n-type clad layer 43c, the etching of the concave portion 51 may be shallow. In other words, the concave portion 51 and the separation groove 54 may be formed which use the first buffer layer 43a, second buffer layer 43b, or n-type clad layer 43c of the n-type semiconductor layer 43 as the bottom surface by which the ohmic contact can be formed.

Besides, in a case where the substrate 41 is formed of semi-insulating GaAs, an n-type contact layer in which the doping amount is adjusted may be formed to be in contact with the substrate 41. And, it is possible to form the concave portion 51 and the separation groove 54 that use the n-type contact layer of the n-type semiconductor layer 43 as the bottom surface, and to form the first metal film 61 on the n-type contact layer.

FIG. 8 shows a front cross-sectional view of the buried layer forming step. In the buried layer forming step, the buried layer 50 formed of SiO₂ is formed on the whole wafer surface. Next, an opening portion for supplying electric power is formed on an upper surface of the ridge portion 49 and on an upper surface of the first metal film 61 by using photolithography and etching.

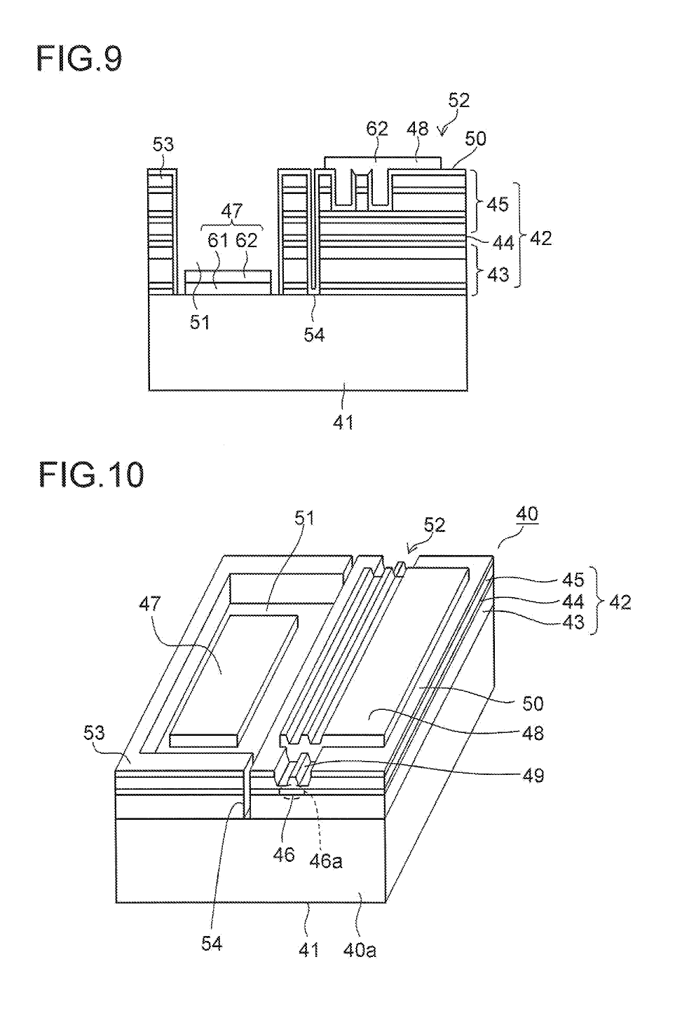

FIG. 9 shows a front cross-sectional view of the second metal film forming step.

In the second metal film forming step, a second metal film 62 is formed on the upper surface of the ridge portion 49 and on the upper surface of the first metal film 61. As to the second metal film 61, a metal film having Au as a main body is formed on the whole wafer surface, and a pattern is formed by using photolithography and etching. In this way, the first contact 47, in which the first, second metal films 61, 62 are laminated, is formed on the bottom surface of the concave portion 51, and the second contact 48 formed of the second metal film 62 is formed on the upper surface of the ridge portion 49.

If the first contact 47 is formed of a single layer formed of the first metal film 61, it is necessary to remove the second metal film 62 from the first metal film 61; accordingly, there is a case where the first metal film 61 is etched and a desired shape is unmaintainable. Because of this, by laminating the second metal film 62 on the first metal film 61 to form the first contact 47 and preventing the first metal film 61 from being etched, it is possible to maintain the desired shape of the first contact 47.

According to the above steps, a semiconductor wafer is formed to be used to produce the semiconductor laser element 40 of one-side-two-contact type in which the first contact 47 and the second contact 48 are disposed on the one side of the substrate 41. In this semiconductor wafer, it is possible to position the structures such as the contact, the ridge-type optical waveguide and the like by means of photolithography. Because of this, it is possible to form a positional relationship among them at high accuracy.

In the lapping step, a rear surface (surface opposite to the surface for forming the semiconductor multilayer 42) of the substrate 41 of the semiconductor wafer is lapped to form the substrate 41 having a predetermined thickness t (see FIG. 2). The substrate 41 is used as a base to be fixed to the slider 10; accordingly, if the thickness t is made large, the heat radiation improves. However, it becomes hard to form the discrete semiconductor laser element 40 (see FIG. 1). Because of this, the thickness t is decided to have a suitable dimension considering the heat radiation and the man-hours at the time of forming the discrete device.

In the first cutting step, a scribe groove is formed on the semiconductor wafer in a direction perpendicular to the ridge portion 49. Next, stress is exerted on the scribe groove to cut the semiconductor wafer by means of cleavage, and a strip-shaped member having the emitting facet 40a (see FIG. 2) on one surface is formed. At this time, it is possible to dispose the scribe groove on the light emitting portion 52 and the protective wall 53 that are formed to have the same height as each other. In this way, there are no wide concaves and convexes in the cleavage direction of the wafer; accordingly, it is possible to prevent deviation in the cleavage direction during the cutting time and thereby to prevent deterioration in the flatness of the emitting facet 40a.

In the coat film forming step, a facet coat film (not shown) is formed on the emitting facet 40a and a facet that opposes the emitting facet 40a. By means of the facet coat film, the facets of the semiconductor laser element 40 are protected and reflectivity of the facets is adjusted. At this time, by means of the protective wall 53, it is possible to prevent the facet coat film from extending onto the first contact 47.

In the second cutting step, a scribe groove is formed on the strip-shaped member in a direction perpendicular to the emitting facet 40a, and stress is exerted on the scribe groove to cut the strip-shaped member by means of cleavage. In this way, the semiconductor laser element 40 is formed to be discrete. At this time, the scribe groove is formed on the protective wall 53; accordingly, it is possible to easily cut the strip-shaped member linearly and thereby to reduce defects caused by curves of the cutting line.

As to the heat-assisted magnetic recording head 1 having the above structure, as shown in FIG. 1, the magnetic recording portion 13 and the magnetic reproducing portion 14 oppose the magnetic disc D, and the slider 10 floats over the magnetic disc D. When a voltage is applied between the first contact 47 and the second contact 48, the laser light propagates through the optical waveguide 46 to be emitted forward (to the slider 10) from the emitting facet 40a.

The laser light emitted from the emitting portion 46 propagates in the optical waveguide 15 of the slider 10 to generate the near-field light. As to the magnetic disc D, the anisotropic magnetic field weakens locally because of the heat of the near-field light, and the magnetic recording is performed by the magnetic recording portion 13. In this way, it is possible to use the magnetic disc D that has large magnetic anisotropic energy and thereby to improve the recoding density of the magnetic disc D.

Besides, the magnetization of the magnetic disc D is detected by the magnetic reproducing portion 14, and it is possible to read data recorded on the magnetic disc D.

The heat generated from the semiconductor laser element 40 caused by the generation of the laser light is conducted to the substrate 41, thereafter, conducted to the slider 10 via the heat-conductive adhesive 19. In this way, the heat is radiated from the substrate 41 and slider 10.

According to the present embodiment, in the semiconductor laser element 40, the substrate 41 is used as the ground to form the semiconductor multilayer 42 by means of epitaxial growth. And, the protective wall 53, which encloses the concave portion 51 in which the first contact 47 is disposed, and the light emitting portion 52, which has the optical waveguide 46 and on which the second contact 48 is disposed, are formed adjacently to each other by means of the semiconductor multilayer 42.

In this way, it is possible to bond the emitting facet 40a of the semiconductor laser element 40 to the slider 10, connect a lead wire to each of the first, second contacts 47, 48, and thereby to form the heat-assisted magnetic recording head 1. Because of this, it is possible to easily perform the positioning between the semiconductor laser element 40 and the slider 10 in such a manner that the emitting portion 46a of the optical waveguide 46 opposes the optical waveguide 15. Besides, when bonding the semiconductor laser element 40, it is possible to prevent the adhesive 19 from adhering to the first contact 47 by means of the protective wall 53 and easily connect the lead wire to the first contact 47. Accordingly, it is possible to achieve the man-hours reduction, yield improvement, and light weight of the heat-assisted magnetic recording head 1.

Further, the substrate 41 and the semiconductor multilayer 42 are joined to each other by means of continuous crystal lattice through epitaxial growth, and the heat conduction between both improves. Besides, when dividing the semiconductor wafer into pieces, the scribe groove is formed on the light emitting portion 52 and the protective wall 53; accordingly, the flatness of the bond surface (emitting facet 40a) formed of the cleavage surface improves. Accordingly, it is possible to improve the heat radiation of the heat-assisted magnetic recording heard 1 that uses the semiconductor laser element 40. In addition, a volume difference between the light emitting portion 52 and the protective wall 53 is small; accordingly, it is possible to even an internal strain of the semiconductor laser element 40 and thereby to improve the stability of the laser light emission.

Here, the concave portion 51 uses the substrate 41 or the n-type semiconductor layer 43 as the bottom surface; accordingly, a short-circuit between the active layer 44 and the first contact 47 and a short-circuit between the p-type semiconductor layer 45 and the first contact 47 are prevented.

Besides, the light emitting portion 52 and the protective wall 53 are separated by the separation groove 54 that uses the substrate 41 or the n-type semiconductor layer 43. In this way, it is possible to more surely prevent the short-circuit between the active layer 44 and the first contact 47 and the short-circuit between the p-type semiconductor layer 45 and the first contact 47.

Besides, the substrate 41 and the active layer 44 are formed of the GaAs-based semiconductor; accordingly, it is possible to easily form the semiconductor multilayer 42 including the active layer 44 by means of epitaxial growth by using the substrate 41 as the ground. In the meantime, if it is possible to produce the semiconductor multilayer 42 by means of epitaxial growth by using the substrate 41 as the ground, the substrate 41 and the active layer 44 may be formed by means of another semiconductor (e.g., InP-based semiconductor and the like).

Besides, there included are the first metal film forming step for laminating the first metal film 61 on the bottom surface of the concave portion 51, and the second metal film forming step for laminating the second metal film 62 on the first metal film 61 and the ridge portion 49. And, the first contact 47 is formed by means of the first metal film 61 and the second metal film 62, and the second contact 48 is formed by means of the second metal film 62. In this way, during the time of forming the second metal film 62, it is possible to prevent the first metal film 61 from being etched and thereby to maintain the desired shape of the first contact 47.

Next, FIG. 10 shows a perspective view of the semiconductor laser element 40 of the heat-assisted magnetic recording head 1 according to a second embodiment. For the sake of description, the same portions as the first embodiment shown in FIG. 2 described above are indicated by the same reference numbers. In the present embodiment, the shape of the protective wall 53 is different from the first embodiment. The other portions are the same as the first embodiment.

The protective wall 53 is opened through a surface that opposes the light emitting portion 52. Even in such a structure, it is possible to obtain the same effects as the first embodiment. Here, the separation groove 54 is formed not to overlap the first contact 47 projected on the emitting facet 40a. In this way, it is possible to prevent the adhesive 19 (see FIG. 1) from adhering to the first contact 47.

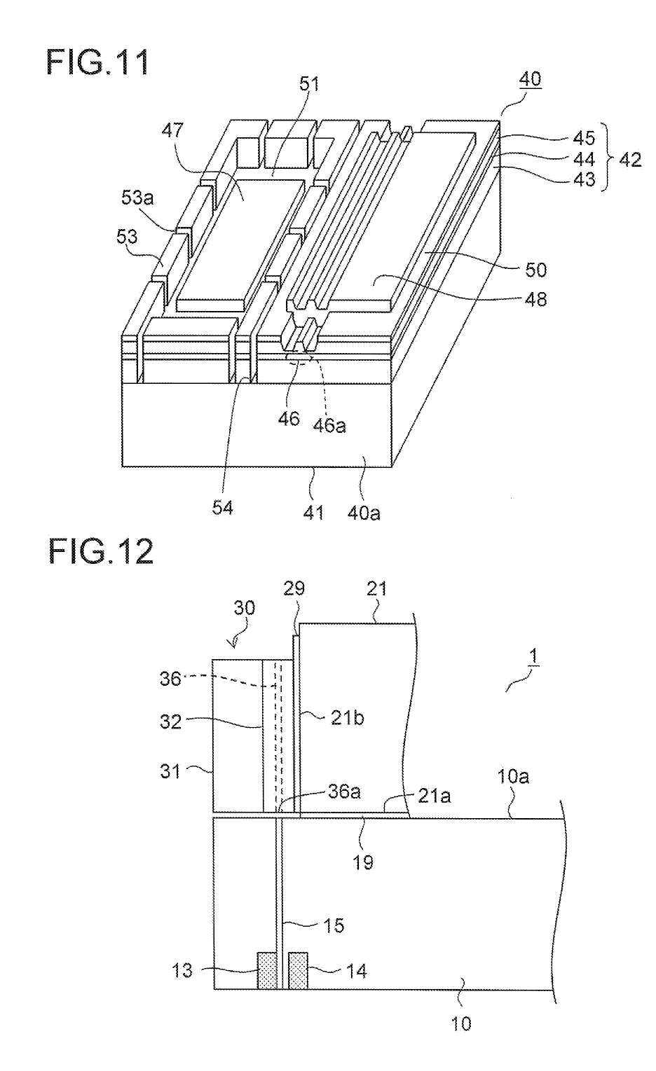

Next, FIG. 11 shows a perspective view of the semiconductor laser element 40 of the heat-assisted magnetic recording head 1 according to a third embodiment. For the sake of description, the same portions as the first embodiment shown in FIG. 2 described above are indicated by the same reference numbers. In the present embodiment, the shape of the protective wall 53 is different from the first embodiment. The other portions are the same as the first embodiment.

The protective wall 53 is cut by groove portions 53a at a plurality of positions in a circumferential direction. Even in such a structure, it is possible to obtain the same effects as the first embodiment. Here, the groove portions 53a are disposed not to overlap the first contact 47 projected on the emitting facet 40a. In this way, it is possible to prevent the adhesive 19 (see FIG. 1) from adhering to the first contact 47. In the meantime, the groove portions 53a may not be formed on the emitting facet 40a.

The semiconductor multilayer 42 of the semiconductor laser element 40 according to the first embodiment is formed of the n-type semiconductor layer 43, the active layer 44, and the p-type semiconductor layer 45 that are laminated in this order on the substrate 41. In contrast to this, in the semiconductor laser element 40 according to the present embodiment, the semiconductor multilayer 42 is formed by laminating the p-type semiconductor layer 45, the active layer 44, and the n-type semiconductor layer 43 in this order on the substrate 41. In this way, it is possible to obtain the same effects as the first embodiment.

In other words, the semiconductor multilayer 42 may be formed on the substrate 41 by successively laminating the first electro-conductive semiconductor layer, the active layer 44, and the second electro-conductive layer. The semiconductor multilayer 42 of the semiconductor laser element 40 of the heat-assisted magnet recording head 1 according to each of the second embodiment and the third embodiment may be formed in the same way as the present embodiment.

The semiconductor laser element 40 of the heat-assisted magnetic recording head 1 according to the first embodiment is formed into the ridge type that has the stripe-shaped ridge portion 49. In contrast to this, the semiconductor laser element 40 according to the present embodiment is formed into an inner stripe type or BH (Buried Heterostructure) type. According to this structure as well, it is possible to obtain the same effects as the first embodiment.

In other words, in the semiconductor laser element 40, the stripe-shaped optical waveguide 46 may be formed by means of the active layer 44. The semiconductor laser element 40 of the heat-assisted magnet recording head 1 according to each of the second embodiment and the third embodiment may be formed in the same way as the present embodiment.

The present invention is usable for a heat-assisted magnetic recording head that performs heat-assisted magnetic recording.

### REFERENCE SIGNS LIST

1 heat-assisted magnetic recording head
10 slider
13 magnetic recording portion
14 magnetic reproducing portion
15 optical waveguide
19 adhesive
21 sub-mount
21a front surface
21b vertical surface
29 solder material
30, 40 semiconductor laser elements
31, 41 substrates
32, 42 semiconductor multilayers
36, 46 optical waveguides
36a, 46a emitting portions
43 n-type semiconductor layer
44 active layer
45 p-type semiconductor layer
47 first contact
48 second contact
49 ridge portion
50 buried layer
51 concave portion
52 light emitting portion
53 protective wall
54 separation groove
61 first metal film
62 second metal film
D magnetic disc

1. A semiconductor laser element comprising:
a substrate formed of a semiconductor, a light emitting portion that includes a semiconductor laminated film in which the substrate is used as a ground to laminate successively a first electro-conductive-type semiconductor layer, an active layer, and a second electro-conductive-type semiconductor layer by means of epitaxial growth; and a stripe-shaped optical waveguide is formed of the active layer,
an annular protective wall that is formed of the semiconductor laminated film adjacently to the light emitting portion and encloses a concave portion which uses the substrate or the first electro-conductive-type semiconductor layer as a bottom surface,
a first electrode disposed on the bottom surface of the concave portion, and
a second electrode disposed on an upper surface of the light emitting portion.

2. The semiconductor laser element according to claim 1, wherein
the light emitting portion and the protective wall are separated by a separation groove that uses the substrate or the first electro-conductive-type semiconductor layer as a bottom surface.

3. The semiconductor laser element according to claim 1, wherein
the protective wall is opened through a surface that opposes the light emitting portion.

4. A heat-assisted magnetic recording head comprising:
the semiconductor laser element according to claim 1 and a slider that performs magnetic recording, wherein
an end surface of the substrate perpendicular to the optical waveguide is bonded to the slider.

5. A method for manufacturing a semiconductor laser element comprising:
a semiconductor laminated film forming step for forming a semiconductor laminated film in which a first electro-conductive-type semiconductor layer, an active layer, and a second electro-conductive-type semiconductor layer are successively laminated on a substrate formed of a semiconductor,
a ridge forming step for forming a stripe-shaped ridge by etching the second electro-conductive-type semiconductor layer,
a concave portion forming step for forming a concave portion enclosed by a protective wall by etching a region adjacent to the ridge to a layer lower than the active layer,
a first metal film forming step for laminating a first metal film on a bottom surface of the concave portion, and
a second metal film forming step for laminating a second metal film on the first metal film and the ridge portion, wherein
a first electrode is formed on the bottom surface of the concave portion by means of the first metal film and the second metal film, and
a second electrode is formed on the ridge portion by means of the second metal film.

6. The semiconductor laser element according to claim 2, wherein
the protective wall is opened through a surface that opposes the light emitting portion.

7. The semiconductor laser element according to claim 1, wherein
the protective wall is cut by groove portions at a plurality of positions in a circumferential direction.

8. The semiconductor laser element according to claim 2, wherein
the protective wall is cut by groove portions at a plurality of positions in a circumferential direction.
